(19) United States
(12) Patent Application Publication
(10) Pub. No.: US 2017/0126141 A1
(43) Pub. Date: May 4, 2017

(54) Switched-Mode Power Supply Unit

(71) Applicant: Siemens Aktiengesellschaft, Muenchen (DE)

(72) Inventors: Janusz DYSZEWSKI, Wien (AT); Stefan RESCHENAUER, Atzelsdorf (AT); Stefan SCHULZ, Gnadendorf (AT)

(21) Appl. No.: 15/320,026

(22) PCT Filed: Jun. 24, 2015
(86) PCT No.: PCT/EP2015/064262

§ 371 Date: Dec. 19, 2016

(30) Foreign Application Priority Data
Jun. 25, 2014 (EP) 14173946.6

(51) Int. Cl. H02M 3/335; G01R 19/25; G01R 15/14; G01K 13/00

(52) U.S. Cl. CPC H02M 3/33546; G01K 13/00; G01R 19/2513; G01R 15/146

(57) ABSTRACT

A switched-mode power supply unit includes at least two LLC resonant converters connected in parallel and which each include a test circuit that generates a respective test signal that is proportionate to the transmitted current of the associated LLC resonant converter, wherein each respective test signal is supplied to a load controller that modifies at least one switching frequency of an LLC resonant converter such that the test signals converge so as to allow the current or load to be accurately split when a plurality of LLC resonant converters is connected in parallel.

### CROSS-REFERENCE TO RELATED APPLICATIONS

This is a U.S. national stage of application No. PCT/EP2015/064262 filed 24 Jun. 2015. Priority is claimed on European Application No. 14173946 filed 25 June. 2014, the content of which is incorporated herein by reference in its entirety.

### BACKGROUND OF THE INVENTION

1. Field of the Invention

The invention relates to a method and switched-mode power supply unit, which comprises at least two LLC resonant converters which are connected in parallel.

2. Description of the Related Art

The term LLC resonant converter is based on the fact that two inductances and a capacitance form an oscillating circuit. Specifically, this means that magnetization inductance and the dispersing inductance (leakage inductance) of a transformer and the capacitance of a resonant converter. Here, the special design of the transformer means that parasitic effects, which are otherwise undesirable, are intentionally used. Sometimes the arrangement of a particular resonance coil is implemented if the leakage inductance of the transformer is insufficient. A high degree of efficiency and a small construction thus result with the LLC resonant converter.

The LLC resonant converter is controlled with a switching frequency, which determines the transformation ratio and thus the output voltage. A change in the switching frequency thus results in a changed transformation ratio. The output voltage can thus be defined in relation to an input voltage. Such a converter is therefore often interpreted as a frequency-dependent voltage source.

If a switched-mode power supply unit with a high output power is required, the component layout becomes increasingly difficult. In particular, the power components must then be suitable for high voltages or currents. It is often more favorable to connect a plurality of LLC resonant converters in parallel with standard components instead of one converter with special power components. The power to be transmitted is then split between the individual converters. This solution is nevertheless still problematic.

With LLC resonant converters that are connected in parallel on the input and output side, the power is namely not automatically split evenly, but instead in accordance with the respective trans formation ratios of the individual converters. The LLC resonant converter with the higher transformation ratio transmits a larger proportion of output power. Here, the resulting output voltage corresponds to an average value of the individual converter output voltages.

Account should foe taken in particular of the frequency behavior of the respective LLC resonant converter, i.e., the dependency of the transformation ratio on the switching frequency. This dependency results from the properties of the resonance components. Component tolerances thus determine differences between resonant converters which are connected in parallel.

If LLC resonant converters are connected in parallel and controlled with the same switching frequency, then the leakage of the component tolerances determines the splitting of the transmitted power. A narrow definition of the tolerances enables the maximum power difference of the converters to be limited. Such a measure is however associated with a corresponding outlay, such as higher component costs.

### SUMMARY OF THE INVENTION

In view of the foregoing, it is an object of the present invention to provide an improved switched-mode power supply unit and a method for controlling the switched mode power supply unit.

These and other objects and advantages are achieved in accordance with the invention by a switched-mode power supply unit in which each LLC resonant converter comprises a measuring circuit, which generates a measuring signal that is proportionate to the transmitted current of the associated LLC resonant converter, where each measuring signal is fed to a load controller and where using the load controller at least one switching frequency of an LLC resonant converter is changed such that the measuring signals converge. The proportion of current transmitted by a respective LLC resonant converter is detected continuously and influenced accordingly by the switching frequency variation, such that the proportions of current are equal to one another. If an LLC resonant converter transmits less currents for instance, then the output voltage of this converter is increased in relation to the other converters. This occurs by adjusting the transformation ratio using switching frequency variation. Specifically the output voltage of the LLC resonant converter with a current proportion that is too low is increased and/or the output voltages of the other converters are lowered. By taking the respective input or output voltage into account, the proportions of transmitted power are then equalized by equalizing the proportions of current.

One significant advantage of the invention is that the current or power can be accurately split when a plurality of LLC resonant converters is connected in parallel. This occurs completely independently of the component tolerances of the individual resonant components.

Each LLC resonant converter therefore transmits a proportion of current or load of exactly the same size, as a result of which no unnecessary reserves have to be provided in the component layout. This advantage signifies the smallest possible installation size for the switched-mode power supply unit.

Moreover, as a result of the even split of power, the individual components of the LLC resonant converter that is connected in parallel therefore reach the same temperatures, which results in a matching service life of all converters.

In an embodiment of the invention, each LLC resonant converter comprises a half-bridge circuit, which is present in each case on an input voltage of the switched-mode power supply unit, where each half-bridge circuit is controlled via a particular control circuit. Each converter is thus firstly controlled independently, as a result of which units constructed in the same way are opposing which, depending on the application, are connected in parallel in corresponding quantities.

It is subsequently advantageous if each control circuit is connected to the load controller to specify a switching frequency change. This creates the possibility of influencing the output voltage of each LLC resonant converter and ensuring the best possible matching of the proportions of power.

In an embodiment, each LLC resonant converter comprises a transformer with a primary winding and two secondary windings, and each secondary winding is connected via an output rectifier to a particular output capacitor. The output capacitors are connected in parallel, here.

In another embodiment of the invention, each respective measuring circuit comprises a temperature sensor, which is arranged adjacent to a power component of the associated LLC resonant converter, such that the measuring signal is proportionate to a heat emitted by this power component. Use is thus made of the effect that a power component with an increasing current flow emits more heat because more losses accumulate. Here, it is favorable if the temperature sensor is arranged adjacent to a power switch or adjacent to a transformer or adjacent to an output rectifier of the associated LLC resonant converter. The losses of these components increase with an increasing current, as a result of which the corresponding heat emission results in a sufficiently accurate measuring signal.

In a further embodiment, each respective measuring circuit for ripple voltage detection is arranged in parallel to a resonant capacitor of the associated LLC resonant converter, and a ripple voltage is supplied to the load controller as a respective measuring signal. Here, the ripple voltage is directly proportionate to the peak value of the primary current. A different power split thus results in a different ripple voltage on the resonant capacitors of the converters which are connected in parallel.

Here, it is favorable if the measuring circuit comprises a voltage converter or a charge pump or a microcontroller for ripple voltage detection. When a microcontroller is used, an analog-digital, converter converts the analog ripple voltage into a digital signal. Further processing using a control algorithm that is set up in the microcontroller is then possible without additional intermediate steps.

In another embodiment, each respective measuring circuit comprises a current measuring element for measuring a current in the associated half-bridge circuit, and a voltage which is proportionate to the measuring current is supplied fed to the load controller as a respective measuring signal. By caking the input or output voltage into account, the currently transmitted power results from the measuring current.

The currant measuring element is simply a shunt resistor, at which the voltage drop is detected as a measured variable.

In an alternative embodiment, each respective measuring circuit comprises a current measuring element for measuring an input current of the associated transformer, and a voltage that is proportionate to the measuring current is supplied to the load controller as a respective measuring signal. By taking the input or output voltage into account, the transmitted power also results from this current measured value. Here, a current converter is favorably used as a current measuring element, because a measuring alternating current is involved.

With the method of regulating the described switched-mode power supply unit in accordance with the invention, a measuring signal is detected for each LLC resonant converter, which is proportionate to the transmitted current of the respective LLC resonant converter, where a control deviation is formed from the measuring signals and where a change variable for at least one switching frequency of an LLC resonant converter is specified therefrom to converge the measuring signals.

In a simple embodiment of the method, only the switching frequency of an LLC resonant converter is controlled using the load controller.

Better results are obtained, in the case of two LLC resonant converters which are connected in parallel, if the switching frequencies of both LLC resonant converters are changed inversely with respect to one another. A rapid stabilization is ensured in this way as power differences develop.

Other objects and features of the present invention will become apparent from the following detailed description considered in conjunction with the accompanying drawings. It is to be understood, however, that the drawings are designed, solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention will now be explained by way of example below with reference to the appended figures, in which:

FIG. 1 schematically shows a parallel connection of two LLC resonant converters with temperature sensors in accordance with the invention;

FIG. 2 schematically shows a parallel connection of two LLC resonant converters with ripple voltage detection in accordance with the invention;

FIG. 3 schematically shows a parallel connection of two LLC resonant converters with current measurement in the respective half-bridge circuit in accordance with the invention;

FIG. 4 schematically shows a parallel connection of two LLC resonant converters with current measurement at the input of the respective transformer in accordance with the invention; and

FIG. 5 is a flowchart of the method in accordance with the invention.

### DETAILED DESCRIPTION OF THE EXEMPLARY EMBODIMENTS

The parallel connection of the two LLC resonant converters 1, 2 is present on a shared input voltage 3. The voltage source 4 is a rectified mains voltage, for instance. The respective half-bridge circuit consists of two switching elements 5, 6 and two resonant capacitors 7, 8 and is connected on the input side to the input voltage 3. Here, the input voltage 3 refers to a ground potential 9. A primary winding 10 of a transformer 11 is arranged in series with a resonance inductance 12 at the output of the half-bridge circuit. The resonance inductance 12 may be a particular coil or a leakage inductance of the transformer 11.

The two switching elements 5, 6 are controlled using a control circuit 13. This generates control pulses, which are transmitted in an electrically isolated manner using a control transmitter, for instance, to the power element of the resonant converter 5, 6. The control circuit 13 is connected to a supply voltage 14 and to the ground potential 9.

Two secondary windings 15, 16 that are connected to an output capacitor 19 via a respective output rectifier 17, 18 are arranged on the secondary side.

The second LLC resonant converter 2 is configured accordingly, where the output capacitors 19 of the two converters 1, 2 are connected in parallel. An output voltage 20 with which a load 21 is energized is present thereon.

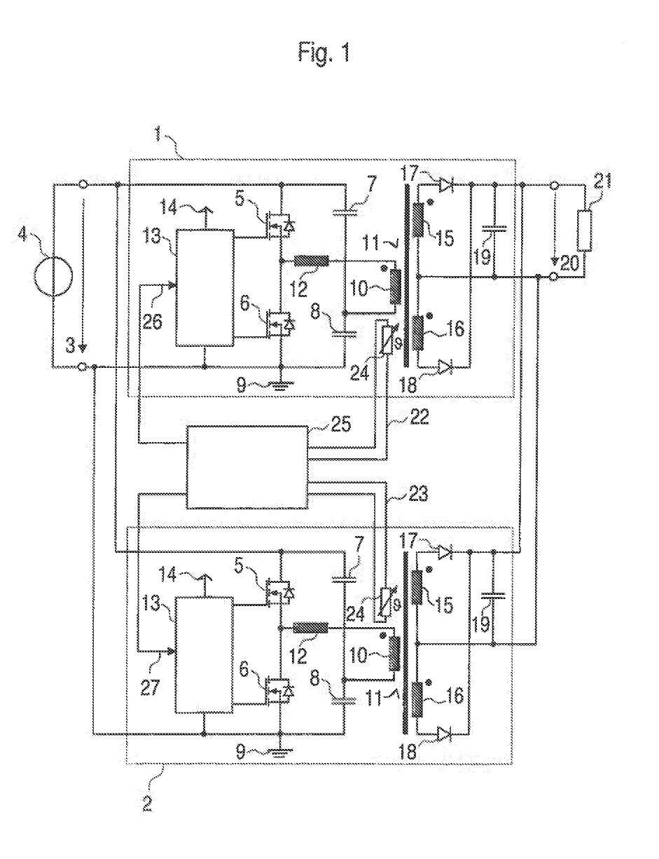

In the embodiment of the invention shown in FIG. 1, each resonant converter 1, 2 comprises a measuring circuit 22, 23 with a temperature sensor 24, which is arranged spatially in close proximity to a power component. This may be the switching elements 5, 6 of the half-bridge circuit, the transformer 11 or the output rectifier 17, 18.

The measured values (e.g., temperature values in degrees Celsius) detected using the temperature sensors 24 are supplied as measuring signals to a shared load controller 25. As soon as a difference occurs between the measuring signals, the load controller 25 outputs a respective control signal 26, 27 to each control circuit 13, by which the respective switching frequency is changed such that the measuring signals converge again. The two resonant converters 1, 2 then operate at different switching frequencies. Here, the respective output voltage of a resonant converter 1, 2 is dependent on the corresponding switching frequency, where the resulting output voltage corresponds to the average value of the individual converter output voltages.

Here, the change in switching frequency occurs, for instance, such that a shared switching frequency is firstly specified to both resonant converters 1, 2, where the switching frequency corresponds to the desired output voltage 20. The load controller 25 then specifies a correction value as a respective control variable 26, 27 to each control circuit 13, with which correction value the shared switching frequency is modified separately for each resonant converter 1, 2.

Alternatively, the load controller 25 is configured such that it specifies an already modified switching frequency to each control circuit 13 as a control variable 26, 27.

In a simpler embodiment, a correction value or a modified switching frequency is specified to just one control circuit 13 to converge the two detected measuring signals.

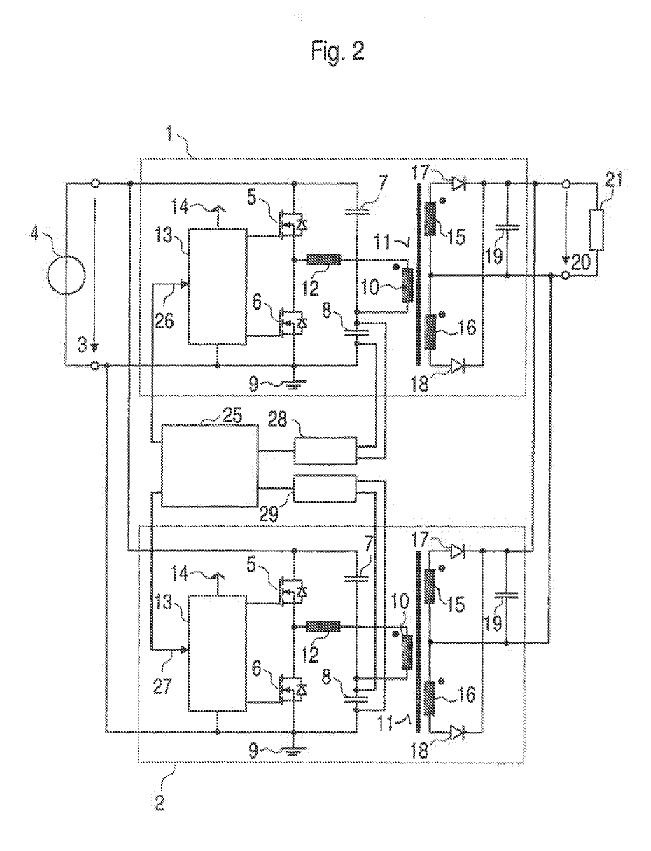

Except for the measuring signal detection, the embodiment shown in FIGS. 2 to 4 each corresponds to that in FIG. 1.

In the embodiment of FIG. 2, a ripple voltage is detected instead of the temperature. To this end, the voltage on a resonant capacitor 8 is continuously tapped and evaluated at the respective resonant converter 1, 2. For this purpose, a measuring circuit 28, 29 for ripple voltage detection is arranged for each resonant converter 1, 2, where the ripple voltage detection provides a corresponding measuring signal to the shared load controller 25.

With power differences between the two resonant converters 1, 2, the load controller 25 operates as described above, in order to converge the measuring signals.

The respective measuring circuit 28, 29 either comprises a voltage converter or a charge pump for detecting the ripple voltage. In a further embodiment, a microcontroller, which detects the ripple voltage in digital form is provided. Here, the microcontroller is favorably also used to implement the load controller 25.

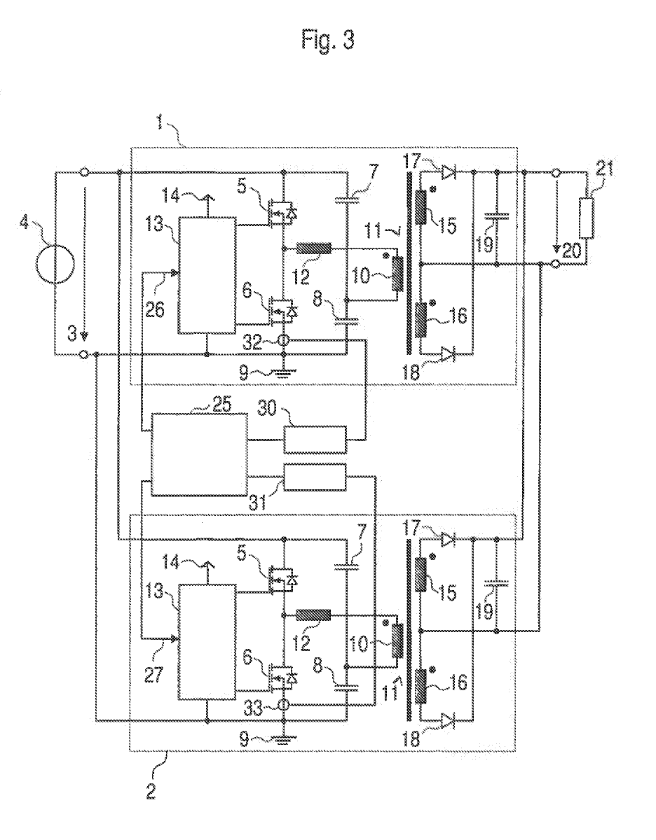

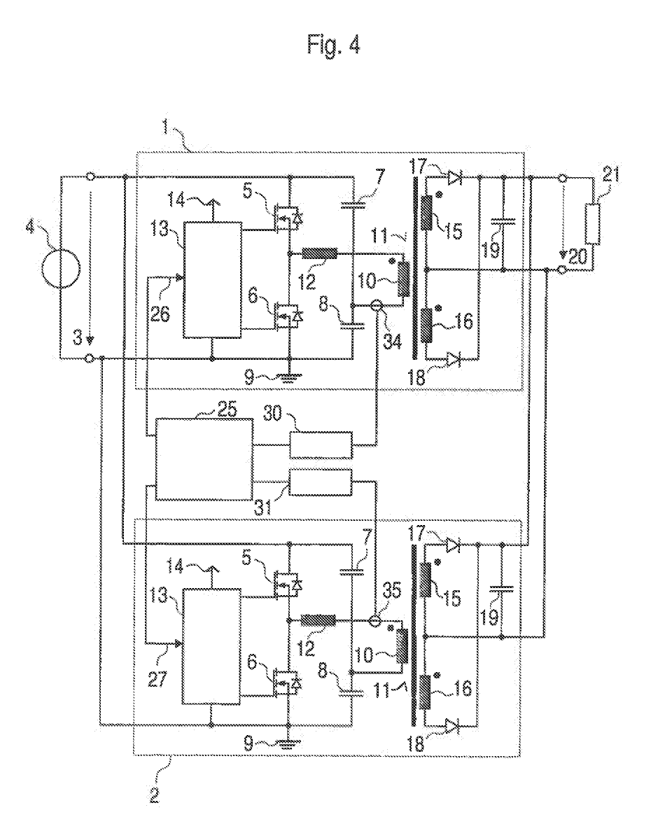

The embodiment shown in FIGS. 3 and 4 comprise a measuring circuit 30, 31 for each resonant converter 1, 2 with a current measuring element 32, 33, 34, 35. The load controller 25 is supplied a voltage as a respective measured value, which is proportionate to the measuring current.

In the embodiment of FIG. 3, the respective current measuring element 32, 33 is arranged directly in the half-bridge circuit. A shunt resistor, at which a measurable voltage drops, is easily provided.

The embodiment of FIG. 4 provides a measurement of the current flowing through the primary winding of the transformer 11. Since this is an alternating currents a current converter can be used, for instance.

In each case the detected current measuring signal is in turn fed to the shared load controller 25, which operates as described above.

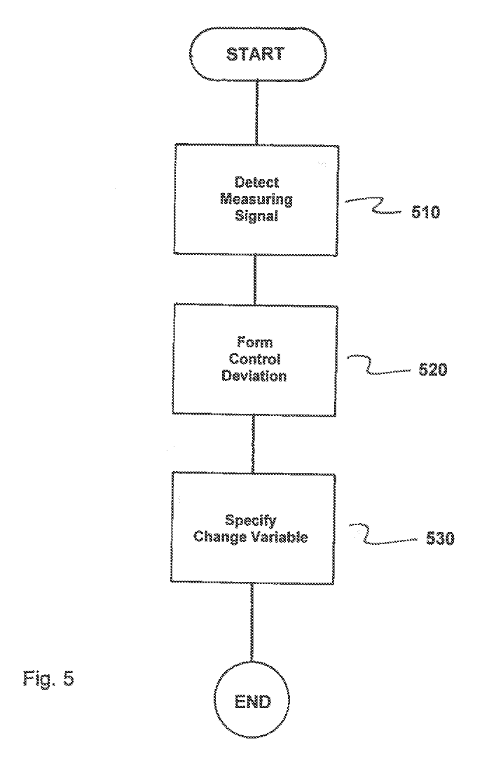

FIG. 5 is a flowchart of the method for controlling a switched-mode power supply unit. The method comprises detecting a measuring signal for each LLC resonant converter of two LLC resonant converters (1, 2), each respective measuring signal being proportionate to a transmitted current of a respective LLC resonant converter (1, 2), as indicated in step 510.

Next, a control deviation is formed from each respective measuring signal, as indicated in step 520.

Next, a change variable is specified from the formed control deviation for at least one switching frequency of an LLC resonant converter (1, 2) to converge the measuring signals, as indicated in step 530.

While there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-15. (canceled)

16. A switched-mode power supply unit, comprising:
at least two LLC resonant converters which are corrected in parallel; and
a load controller;
wherein each LLC resonant convener comprises a measuring circuit, which generates a respective measuring signal which is proportionate to the transmitted current of the associated LLC resonant converter;
wherein each measuring signal is supplied to the load controller and at least one switching frequency of an LLC resonant converter of the at least two LLC resonant converters which are connected in parallel is changed via the load controller such that measuring signals converge.

17. The switched-mode power supply unit as claimed in claim 16, wherein each LLC resonant converter comprises a half-bridge circuit, which is at each input voltage of the switched-mode power supply unit; and
wherein each half-bridge circuit is controlled via a particular control circuit.

18. The switched-mode power supply unit as claimed in claim 17, wherein each control circuit is connected to the load controller for specifying a switching frequency change.

19. The switched-mode power supply unit as claimed in claim 16, wherein each LLC resonant converter comprises a transformer including a primary winding and two secondary windings; and
wherein each secondary winding of the two secondary windings is connected via an output rectifier to a particular output capacitor.

20. The switched-mode power supply unit as claimed in claim 17, wherein each LLC resonant converter comprises a transformer including a primary winding and two secondary windings; and
wherein each secondary winding of the two secondary windings is connected via an output rectifier to a particular output capacitor.

21. The switched-mode power supply unit as claimed in claim 18, wherein each LLC resonant converter comprises a transformer including a primary winding and two secondary windings; and
wherein each secondary winding of the two secondary windings is connected via an output rectifier to a particular output capacitor.

22. The switched-mode power supply unit as claimed in claim 16, wherein each respective measuring circuit comprises a temperature sensor arranged adjacent to a power component of the associated LLC resonant converter such that the measuring signal is proportionate to heat emitted by the power component.

23. The switched-mode power supply unit as claimed in claim 22, wherein the temperature sensor is arranged adjacent to one of (i) a power switch, (ii) a transformer and (iii) an output rectifier of an associated LLC resonant converter.

24. The switched-mode power supply unit as claimed in claim 16, wherein each respective measuring circuit detects ripple voltages and is arranged in parallel with a resonant capacitor of an associated LLC resonant converter; and
wherein a ripple voltage is supplied to the load controller as a respective measuring signal.

25. The switched-mode power supply unit as claimed in claim 24, wherein the measuring circuit comprises one of (i) a voltage converter, (ii) a charge pump and (iii) a microcontroller for ripple voltage detection.

26. The switched-mode power supply unit as claimed in claim 17, wherein each respective measuring circuit comprises a current measuring element for measuring current in an associated half-bridge circuit; and
wherein a voltage proportionate to the measuring current is supplied to the load controller as a respective measuring signal.

27. The switched-mode power supply unit as claimed in claim 18, wherein each respective measuring circuit comprises a current measuring element for measuring current in an associated half-bridge circuit; and
wherein a voltage proportionate to the measuring current is supplied to the load controller as a respective measuring signal.

28. The switched-mode power supply unit as claimed in claim 19, wherein each respective measuring circuit comprises a current measuring element for measuring current in an associated half-bridge circuit; and
wherein a voltage proportionate to the measuring current is supplied to the load controller as a respective measuring signal.

29. The switched-mode power supply unit as claimed in claim 26, wherein the current measuring clement comprises a shunt resistor.

30. The switched-mode power supply unit as claimed in claim 19, wherein each respective measuring circuit comprises a current measuring element for measuring an input current of the associated transformer; and
wherein a voltage proportionate to the measuring current is supplied to the load controller as a respective measuring signal.

31. The switched-mode power supply unit as claimed in claim 30, wherein the current measuring element comprises a current converter.

32. A method for controlling a switched-mode power supply unit, the method comprising:
detecting a measuring signal for each LLC resonant converter of two resonant conveners, each respective measuring signal being proportionate to a transmitted current of a respective LLC resonant converter;
forming a control deviation from each respective measuring signal; and
specifying a change variable from the formed control deviation for at least one switching frequency of an LLC resonant converter to converge the measuring signals.

33. The method as claimed in claim 32, wherein only a switching frequency of an LLC resonant converter is controlled via a load controller.

34. The method as claimed in claim 32, wherein switching frequencies of both LLC resonant converters are changed inversely relative to one another with the two LLC resonant converters connected in parallel.
